(19) United States
(12) Patent Application Publication
(10) Pub. No.: US 2015/0118833 A1
(43) Pub. Date: Apr. 30, 2015

(54) METHOD OF MAKING SOURCE/DRAIN CONTACTS BY SPUTTERING A DOPED TARGET

(71) Applicant: Applied Materials, Inc., Santa Clara, CA (US)

(72) Inventors: Jianxin LEI, Fremont, CA (US); Jothilingam RAMALINGAM, Sunnyvale, CA (US); Chi-Nung NI, Foster City, CA (US)

(21) Appl. No.: 14/062,741

(22) Filed: Oct. 24, 2013

(51) Int. Cl. H01L 21/285; H01L 29/66; C23C 14/34; H01L 21/225

(52) U.S. Cl. CPC H01L 21/28506; H01L 21/225; H01L 29/66477; C23C 14/3414
USPC 438/558; 204/298.13

(57) ABSTRACT

A method of depositing a contact layer material includes sputtering a target including a metal and a dopant. The contact layer material is conductive and may be used in a transistor device to connect a conductive region, such as a source region or a drain region of metal-oxide semiconductor field effect transistor, to a contact plug. The contact plug is used to connect the source/drain region formed in a semiconducting substrate to metal wiring layers formed above the gate level of a semiconductor device. The resulting contact layer may be a metal silicide including the dopant. In some embodiments, the sputtered metal may be nickel and the dopant may be phosphorous and the resulting contact layer a nickel silicide doped with phosphorous. Embodiments described, in general, can provide reduced contact resistance and thus improved performance in semiconductor devices.

### BACKGROUND

1. Field of the Invention

Embodiments generally relate to manufacture of semiconductor devices by sputtering a doped target.

2. Description of the Related Art

In the manufacturing of semiconductor devices, such as metal-oxide-semiconductor field effect transistor (MOSFET) devices, the electrical resistance between various portions of the device, for example, source and drain electrodes, is an important component of overall device performance. In general, lower resistance is preferred in the intended electrical pathways of a semiconductor device because lower resistance will reduce power consumption and also reduce so-called “RC delay,” which is a function of electrical resistance and parasitic capacitance.

The electrical resistance between a MOSFET source electrode and drain electrode may be referred to as “total series resistance.” Total series resistance may be broken down into various components, such as the resistance of the conductive materials in the conductance pathway and the resistance in connections (junctions) between conductive materials in the pathway.

As distances between various portions of the semiconductor device are reduced, the conductance pathways between the various portions are also generally made smaller in size, which serves to increase total series resistance if the cross-sectional area of conductance pathway is reduced. For example, the size of the connection interface between electrode/wiring metal and the source/drain region of a MOSFET has generally decreased by approximately 30% with each new CMOS (complementary metal-oxide-semiconductor) technology node (e.g., the 65 nm node, the 45 nm node, the 32 nm node, etc.).

A significant percentage of the total series resistance is the result of resistance at the connections between different conductive materials in the conductance pathways. Thus, if the total series resistance in a semiconductor device is to be maintained or reduced in future devices, there is a need in the art to reduce the resistance in the connections between conductive materials.

### SUMMARY

In a first embodiment, a method of forming a MOSFET device includes depositing a contact layer material comprising a metal and a dopant onto a conductive region formed in a semiconductor material. The contact layer material is conductive and deposited by sputtering of a target including the metal and the dopant.

In a second embodiment, a method of forming a semiconductor device include providing a semiconductor substrate having at least one conductive region that is a source region or a drain region. The semiconductor substrate is positioned in a physical vapor deposition chamber that has a target comprising a metal and a dopant. The target is sputtered to deposit the metal and the dopant onto the conductive region. The semiconductor substrate on which the metal and the dopant have been deposited is then annealed.

In a third embodiment, an apparatus includes a physical vapor deposition chamber and a sputter target comprising a metal, such as nickel, and a dopant, such as phosphorous.

### BRIEF DESCRIPTION OF THE DRAWINGS

A more particular description of example embodiments of the present disclosure is provided by reference to the appended drawings. It is to be noted, however, that the appended drawings illustrate only example embodiments and are therefore not to be considered limiting the scope of the present disclosure which may admit to other equally effective embodiments. Furthermore, the drawings may include simplified representations of actual components thus, for example, elements well-known in the art may be omitted. Additionally, the elements depicted in the drawings are generally not to scale and the depicted relative sizes of elements in a single drawing or across multiple drawings may also be different from the relative sizes of elements in actual devices fabricated according to embodiments of the present disclosure.

FIG. 1 is a conceptual diagram depicting a portion of a MOSFET semiconductor device having a contact layer deposited by sputtering a doped target.

FIG. 2 is a graph depicting a known relationship between contact resistance and the difference in work function of materials at an interface.

FIG. 3 provides determined values for specific contact resistance of annealed and pre-annealed embodiments.

FIG. 4 is a conceptual diagram depicting an apparatus for depositing a material according to an embodiment of the present disclosure.

FIG. 5 is a process flow chart depicting a method according to an embodiment of the present disclosure for depositing a material with reduced contact resistance.

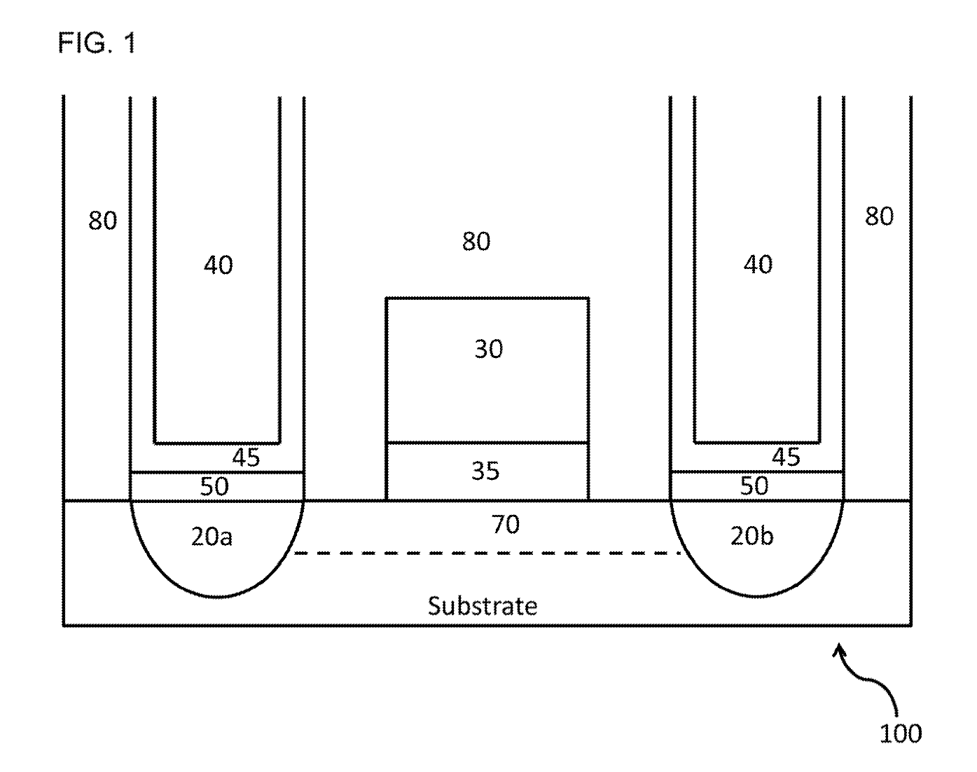

As depicted in FIG. 1, a semiconductor device such as a MOSFET 100 includes a first conductive region 20a and a second conductive region 20b (which can be collectively referred to as conductive regions 20a, 20b) that can function as source regions or drain regions of the MOSFET 100. Each conductive region is typically formed in a region of semiconductor substrate 10 by a method such as ion implantation. Conductive regions 20a, 20b include, for example, n-type dopants sufficient to allow the conductive region to be electrically conductive by making donor electrons available. If semiconductor substrate 10 is, for example, silicon (Si), then the n-type dopants would include phosphorous (P) and arsenic (As) atoms. Other n-type dopants would include elements, such as antimony (Sb), in Group V of the classic periodic table.

Semiconductor substrate 10 can be an undoped, intrinsic semiconductor or include dopants in specific regions or dispersed throughout its entirety. Semiconductor substrate 10 can include, for example, p-type dopants, such as boron (B) and aluminum (Al), which are electron acceptors. Semiconductor substrate 10 may have, for example, only specific regions doped with p-type dopants or these dopants may be dispersed throughout its entirety.

MOSFET 100 includes a gate electrode 30 on a gate insulation film 35. The gate electrode 30 is a conductive material, for example, doped polysilicon or a metal. The gate electrode 30 is positioned between the conductive regions 20a, 20b. By applying an electric potential to the gate electrode 30, the conductance in channel 70 between each first conductive region 20a, configured as a source region, and each second conductive region 20b, configured as a drain region, can be varied.

In general, conductive regions 20a, 20b are typically electrically connected to a power supply potential or the like, such as a relatively high potential or a relatively low potential (e.g., a ground potential). Electrical connections between the power supply potential and the conductive regions are typically made through metal wiring connections in device layers formed above the semiconductor substrate 10. These other devices layers above the conductive regions 20a, 20b are not specifically depicted in FIG. 1, but as well-known in the art the initial connection between conductive regions and the above-formed wiring layers can be made using a contact plug 40. Contact plug 40 may be, for example, a metal such as tungsten (W), aluminum (Al), gold (Au), platinum (Pt), palladium (Pd), and various conductive alloys.

In the MOSFET 100 fabrication process, contact plug 40 is formed by depositing a metal into an opening formed in an insulating material 80 provided on the semiconductor substrate 10. A conformal-deposited barrier layer 45 may first be deposited in the opening. Barrier layer 45 is intended to limit electro-migration of the contact plug 40 material into conductive region 20 and insulating material 80. Barrier layer 45 may be, for example, titanium nitride, a tantalum alloy, or a tungsten-titanium alloy. Barrier layer 45 may be optionally conformally deposited or omitted.

MOSFET 100 further includes the contact layer 50 between contact plug 40 and conductive region 20. The contact layer 50 serves as a junction between dissimilar materials, namely a semiconducting material and a metallic material. Contact layer 50 may be, for example, a silicide compound. If barrier layer 45 is provided, contact layer 50 may be in direct contact with barrier layer 45 rather than contact plug 40.

Total series resistance (R_{T}) in the conductance pathway between source electrode and drain electrode is the sum of all resistances between the contact plug 40 above the source region (conductive region 20a) and the contact plug 40 above drain region (conductive region 20b). Total series resistance (R_{T}) may be represented by the following equation:

R_{T}=R_{channel}+Rₑₓₜ (1)

Thus, total series resistance (R_{T}) includes the resistance due to the material in the conductance channel (R_{channel}) and the so called external resistance (Rₑₓₜ). R_{channel} is determined by the intrinsic properties of the semiconducting material forming the conductance channel and other factors such as the length and cross-section of the conductance channel.

External resistance (Rₑₓₜ) may be represented by the following equation:

Rₑₓₜ=R_{plug}+R_{c}+R_{sdb}+Rₒₜₕₑᵣ (2)

where R_{plug} is the resistance due to the contact plug material, R_{c} is the contact resistance at the junction between contact plug material and source/drain region material, R_{sdb} is the resistance due to the source/drain region material, and Rₒₜₕₑᵣ is all other resistances present between contact plug and conductance channel. In general, contact resistance (R_{c}) is a significant contributor to external resistance Rₑₓₜ and can account for approximately 25% to 35% of Rₑₓₜ in existing devices.

Contact resistance (R_{c}) is the electrical resistance at the junction/interface between metal and semiconductor material, that is, in MOSFET 100, at the interface of contact plug 40 (or barrier layer 45) and the conductive regions. In MOSFET 100, contact resistance (R_{c}) more specifically refers to the electrical resistance at the interface between contact layer 50 and the conductive regions 20a, 20b.

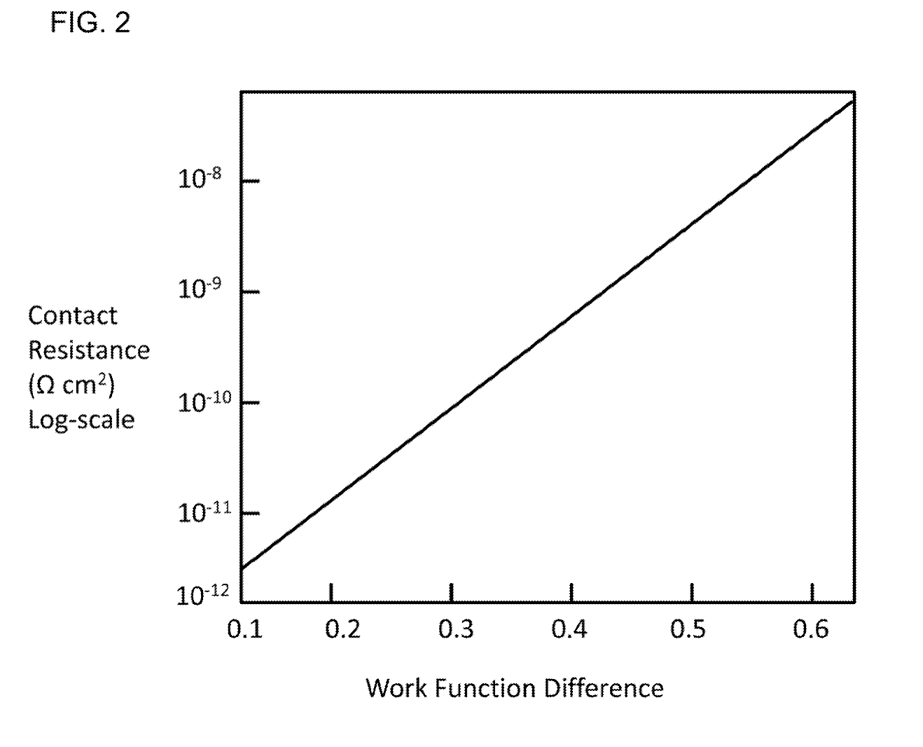

Contact resistance (R_{c}) is a function of differences in work function between the metal and the contacted semiconductor material. As depicted in FIG. 2, reducing the difference in work function between the junction materials (which may be referred to as reducing the metal/junction Schottky barrier height), reduces contact resistance (R_{c}). Contact resistance is also a function of the doping level in the junction, with generally an increase in doping levels causing a decrease in resistance. Thus, in MOSFET 100, contact resistance (R_{c}) is a function of the difference in the work function of contact layer 50 and conductive regions 20a, 20b and the doping level in the junction between the contact layer 50 and conductive regions 20a, 20b.

Contact resistance (R_{c}) can also depend on other factors, such as mean surface roughness at the interface, but, in general, contact resistance (R_{c}) is proportional to the specific contact resistance (ρ_{c}). Specific contact resistance (ρ_{c}) can be described by the following equation:

ρ_{c}=C₁e^{(C}^{₂}^{×q×Φ}^{_{B}}^{/√(Nif))} (3)

where q is dopant charge, N_{if} is interfacial dopant concentration and Φ_{B} is the Schottky barrier height. In equation 3, the square root of N_{if} is taken. C₁ is a constant related to the characteristics of metal and semiconductor at the interface; and C₂ is a constant related to the effective electron mass of the charge carrier. As seen in equation 3, there are two pathways to lowering ρ_{c}. Lowering the Schottky barrier height (Φ_{B}) or increasing interfacial dopant concentration (N_{if}).

According to an embodiment, a contact layer 50 is formed between contact plug 40 and the conductive regions 20a, 20b to reduce the contact resistance (R_{c}) between the metal of contact plug 40 (or barrier layer 45) and the conductive regions 20a, 20b. Reducing R_{c} reduces Rₑₓₜ and R_{T}, per equation 1 and equation 2. In general, reducing total series resistance (R_{T}) will improve overall device performance.

The material of contact layer 50 in this first embodiment includes a metal and a dopant. For example, contact layer 50 can include nickel (Ni) as a metal and a phosphorous (P) impurity as a dopant. The atomic concentration of the dopant in the metal can be, for example, 0.1% to 1%. Higher concentrations of the dopant maybe preferable for reducing the resistance in contact layer 50. The contact layer 50 can comprise a metal silicide material, for example, if the conductive region includes silicon. In one embodiment, the material of contact layer 50 can comprise a nickel silicide material including a phosphorous impurity.

The material of contact layer 50 can be deposited by, for example, a physical vapor deposition process. In a physical vapor deposition process, a metal target including a dopant may be sputtered to form contact layer 50. The atomic concentration of the dopant in the target may be, for example, 0.1% to 1%, or higher. In an example embodiment, the metal target is nickel (Ni) and includes 1% (atomic concentration) phosphorous (P). The sputtering process can optionally be a radio-frequency plasma assisted physical vapor deposition (RFPVD) process.

After initial deposition, the material of contact layer 50 can optionally be annealed. The annealing may be at any appropriate temperate and for any appropriate time. For example, the annealing may be at a temperature of 200° C. to 1000° C. More specifically, the annealing may be at approximately 750° C. to 850° C. The annealing process can be a dynamic sub-millisecond anneal process performed by, for example, laser spike processing by which the layer/substrate is rapidly heated by exposure to a laser pulse or pulses. The annealing may be a rapid thermal annealing process involving, for example, heat lamps and/or hotplates. The anneal may be performed in the deposition tool or on a different tool, such as a separate furnace, oven, or hotplate.

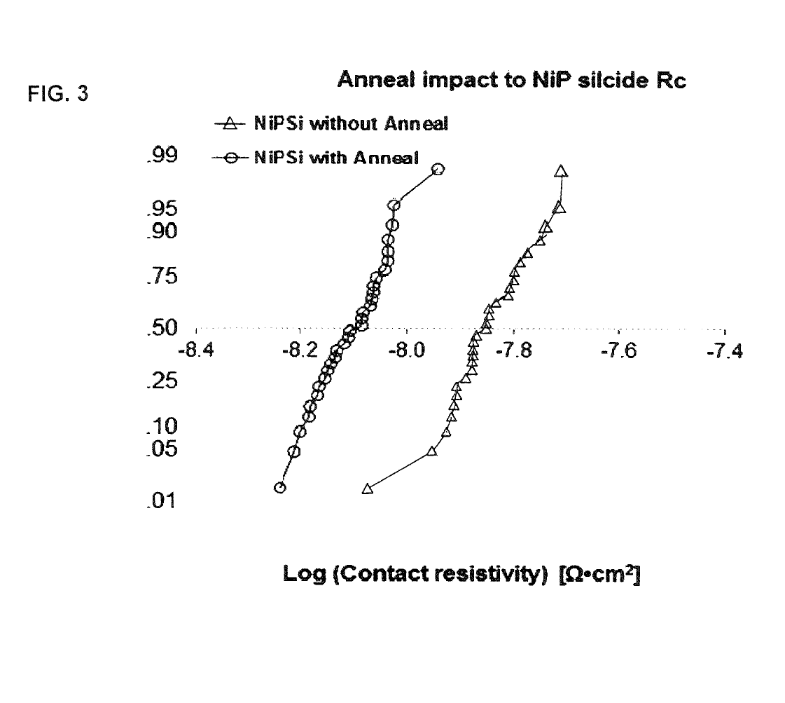

FIG. 3 depicts a measured specific contact resistance (ρ_{c}) of a deposited phosphorous-doped nickel silicide film with and without an annealing process. In the data presented in FIG. 3, specific contact resistance (ρ_{c}) for the contact layer 50 has been determined by a transmission line model (TLM) known in the art in which resistance across test structures including multiple contact points is measured and ρ_{c} determined by fitting experimental data. The contact material reported in FIG. 3 was a phosphorous-doped nickel silicide material deposited in an RFPVD process using a nickel target doped with 1% (atomic concentration) phosphorous. The annealing process was a dynamic sub-millisecond anneal process at 800° C. For phosphorous doped nickel silicide ρ_{c} is approximately 8.0×10⁻⁹ for the annealed material and 1.4×10⁻⁸ for the material that was not annealed.

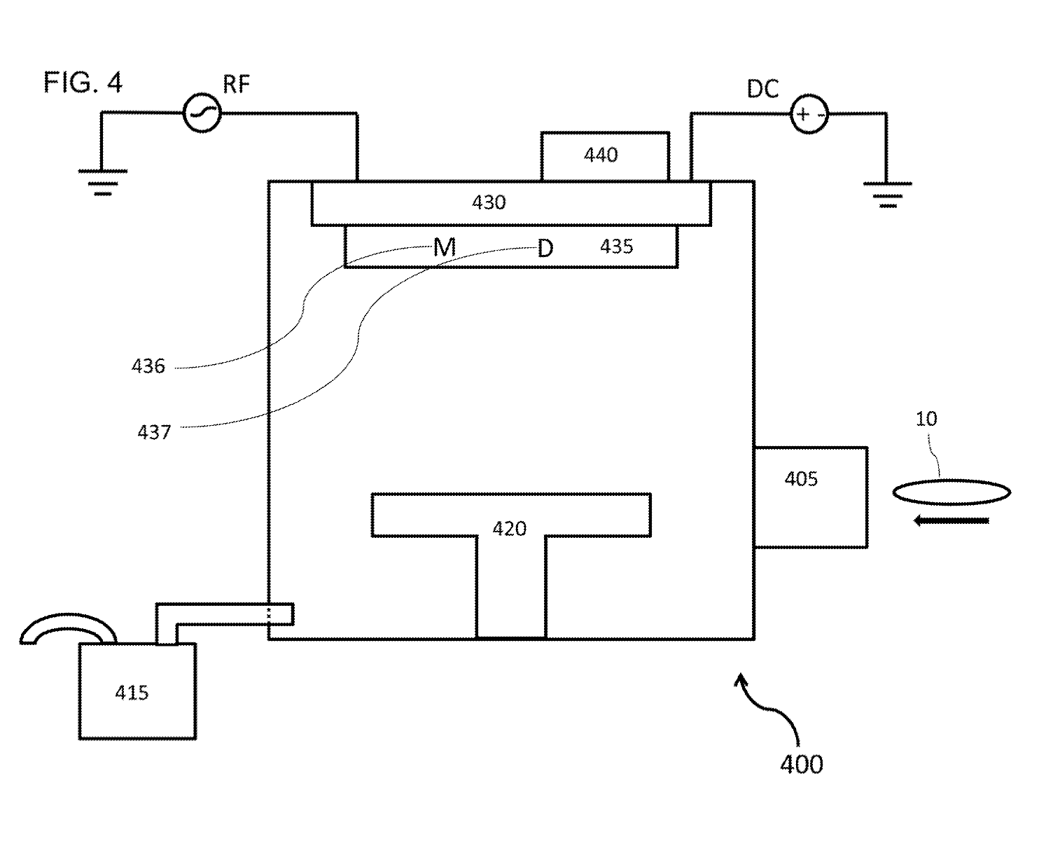

FIG. 4 depicts an example embodiment of an apparatus 400 used in forming a semiconductor device with reduced contact resistance, such as MOSFET 100. Apparatus 400 comprises a chamber 410 that includes an opening 405 allowing a semiconductor substrate 10 to be positioned on substrate holder 420. Generally, chamber 410 may be sealed and the interior of chamber 410 may be placed in a state of vacuum. Vacuum pump 415 may be provided to place the interior of chamber 410 in the state of vacuum. Substrate holder 420 may be optionally allow for control of the temperature of semiconductor substrate 10 during processing, for example, semiconductor substrate 10 may be cooled below room temperature or heated to above room temperature. Room temperature is nominally 25° C.

Apparatus 400 includes a target holder 430 for holding a target 435. Apparatus 400 may optionally include means for heating or cooling the target 435. The target 435 may also be rotated or moved during deposition processes. Target 435 includes a metal 436 and a dopant 437. The material (e.g., metal 436 and dopant 437) from target 435 is deposited on semiconductor substrate as part of the process for forming a contact layer 50. At least a portion of target 435 is exposed to a volatilizing energy causing the material (e.g., metal 436 and dopant 437) of target 435 to be sputtered and/or enter a gaseous or plasma state. Some portion of the material from target 435 is then condensed on semiconductor substrate 10. Material from target 435 may be sputtered by localized heating, exposure to electron beam energy, laser beam energy, plasma discharge, or combinations thereof. In the example depicted in FIG. 4, magnetron 440 generates sputters material from target 435 which is deposited on substrate 10 on the substrate holder 420.

Apparatus 400 can optionally incorporate DC electrodes for biasing the substrate holder 420 relative to the target holder 430 and RF power generators for forming a RF plasma in chamber 410 for RFPVD processing.

The deposition process in apparatus 400 may involve various purge cycles, target conditioning steps, and/or surface preparation steps. Surface preparation steps may include exposing semiconductor substrate 10 to a RF plasma to remove surface contaminates and/or upper portions of the conductive regions 20a, 20b.

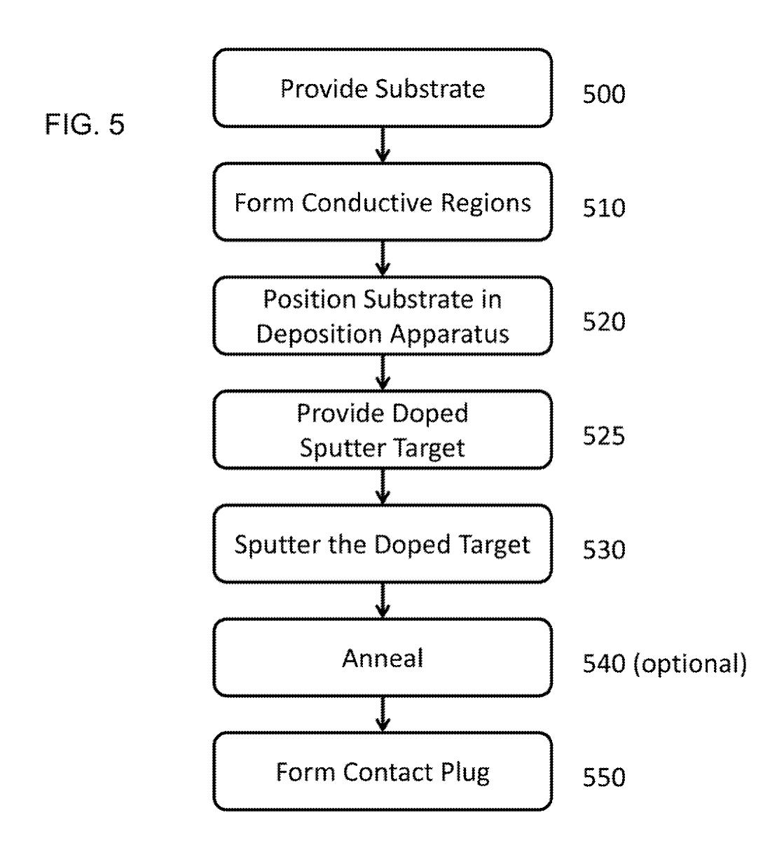

A method for forming a semiconductor device including a contact layer with reduced contact resistance, such as contact layer 50, is depicted in FIG. 5.

In step 500, a substrate such as a semiconductor wafer is provided. The substrate may be, for example, a silicon wafer, a silicon-germanium (SiGe) wafer, or a silicon-on-insulator (SOI) wafer.

In step 510, using standard semiconducting device fabrication processes, such as photolithography, ion implantation, thermal diffusion, and/or epitaxial growth, conductive regions are formed in the substrate. The conductive regions are formed by inclusion of dopants in a semiconducting material such as in a portion of the substrate. The conductive regions may be used as source/drain regions of a transistor device, such as MOSFET 100.

Gate electrode portions of the transistor device may be formed before or after the formation of the source/drain regions, but are commonly formed after the source/drain regions. An insulating film with openings above the source/drain regions may be formed on the substrate.

The conductive regions, such as source and drain regions, may be formed with n-type or p-type dopants. Concentration of the dopant in the conductive regions may be approximately 1×10²⁰/cm³ to 1×10²¹/cm³, whereas the silicon atomic density is about 5×10²²/cm³.

In step 520, the substrate with the conductive regions is positioned in a deposition apparatus such as, for example, apparatus 400 described above.

A sputter target including a metal and a dopant is provided in step 525. Though depicted in FIG. 5 as occurring after positioning the substrate in the deposition apparatus, this specific ordering is not required and the sputter target can be provided at any point before step 530.

The metal of the sputter target can be, for example, nickel, nickel alloys, a rare earth metal, an alloy of a rare earth metal. Rare earth metals include lanthanides, yttrium, and scandium.

The dopant of the sputter target can be, for example, n-type dopants, such as phosphorous (P), arsenic (As), and antimony (Sb). The concentration of the dopant in the target may be between 0.1% and 5% by atomic concentration.

In step 530, at least a portion of the sputter target is volatilized (e.g., sputtered) and then some portion of the volatilized material is condensed on the substrate. Multiple sputter targets comprising different materials can be sputtered simultaneously or in sequence.

Because the sputter target contains a metal and a dopant, the dopant will generally be volatilized with the metal and will also condense on the substrate. The concentration of the dopant in the deposited material need not be the same as the concentration of the dopant in the sputter target, though this could occur. Additional processing steps may be performed to increase the concentration of dopant in the deposited material. For example, ion implantation may be performed after sputter deposition to increase the dopant concentration.

In step 540, the deposited material is optionally annealed. The annealing may occur in the same apparatus in which the deposition takes place or in a different apparatus. The annealing may be a rapid thermal annealing process. A laser spike annealing (e.g., dynamic sub-millisecond thermal annealing) process may be used to anneal the deposited material.

During the annealing process, the deposited material may form a silicide. Silicon atoms may be provided the conductive regions, assuming the semiconducting material of the substrate includes silicon, or by other layers or by materials deposited with or on the contact layer material.

The annealing process need not be a discrete process, but may occur during various subsequent processing steps during the fabrication of the semiconductor device. That is, annealing may occur in several stages and/or may occur during a later fabrication step.

In step 550, the contact plug is formed on the deposited material of the contact layer. As part of the contact plug formation process a metal barrier layer may optionally be deposited on the contact layer before the contact plug material.

In subsequent processing steps, various metal wiring layers can be formed on the substrate and the source/drain regions connected via contact plugs to wiring layers as required by the desired circuit design.

While the preceding description is directed to example embodiments of the present disclosure, other and further embodiments of the present disclosure may be devised without departing from the basic scope thereof, and the scope thereof is determined by the claims that follow.

What is claimed:

1. A method, comprising:
forming a conductive region in a semiconductor material; and
depositing a contact layer material comprising a metal and a dopant on the conductive region, wherein the contact layer material is conductive and deposited by sputtering a target including the metal and the dopant.

2. The method of claim 1, wherein the metal is nickel and the dopant is phosphorous.

3. The method of claim 2, further comprising:
annealing the contact layer material after the contact layer material is deposited on the conductive region.

4. The method of claim 3, wherein the annealing step generates a silicide.

5. The method of claim 3, wherein the annealing step includes a rapid thermal anneal process.

6. The method of claim 3, wherein the annealing is at temperature between 300° C. and 900 ° C.

7. The method of claim 3, wherein the annealing includes a laser spike process.

8. The method of claim 1, wherein an atomic concentration of the dopant in the target is approximately 1%.

9. The method of claim 1, wherein an atomic concentration of the dopant in the target is between approximately 0.1% and 5%.

10. The method of claim 1, wherein the target is approximately 99% nickel and approximately 1% phosphorus in atomic composition.

11. The method of claim 1, wherein the dopant is one of phosphorous, arsenic, antimony, sulfur, and selenium.

12. The method of claim 1, wherein the metal is one of nickel, a nickel alloy, a rare earth metal, and an alloy of a rare earth metal.

13. The method of claim 1, wherein the deposition of the contact layer material uses radio frequency enhanced physical vapor deposition.

14. A method of forming a semiconductor device, the method comprising:
positioning a semiconductor substrate in a physical vapor deposition chamber having a sputter target that includes a metal and a dopant, wherein the semiconductor substrate has a conductive region that is one of a source region and a drain region;
sputtering the sputter target to deposit the metal and the dopant on the conductive region; and
annealing the semiconductor substrate on which the metal and the dopant have been deposited.

15. The method of claim 14, wherein the metal is nickel and the dopant is phosphorous.

16. The method of claim 15, wherein the atomic concentration of phosphorous in the sputter target is 1%.

17. The method of claim 15, wherein the semiconductor substrate includes silicon.

18. The method of claim 14, further comprising:
forming a contact plug on the deposited metal and dopant.

19. An apparatus, comprising:
a physical vapor deposition chamber; and
a sputter target including nickel and phosphorous.

20. The apparatus of claim 19, wherein the atomic concentration of phosphorous in the sputter target is approximately 1%.
